(19) United States
(12) Patent Application Publication
(10) Pub. No.: US 2026/0255647 A1
(43) Pub. Date: Aug. 27, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Yun-Ting Chiang, Hsinchu County (TW); Yu-Jhen Jiang, Hsinchu (TW); Chun-Cheng Chou, Taichung City (TW)

(73) Assignee: Taiwan Semiconductor Manufacturing Company, Ltd., Hsinchu (TW)

(21) Appl. No.: 19/059,782

(22) Filed: Feb. 21, 2025

(51) Int. Cl. H10D 64/23; H01L 21/02; H01L 21/3065; H10D 30/00

(52) U.S. Cl. CPC H10D 64/251; H10D 30/501; H10P 50/242; H10P 70/27

(57) ABSTRACT

A method includes: forming a dielectric liner in an opening above a source/drain (S/D) feature in a semiconductor structure; forming a recess in the S/D feature through the opening via plasma etching; removing a byproduct from forming the recess via a wet cleaning process; and forming a silicide contact that extends from a sidewall of the opening above the S/D feature to a bottom of the opening in the recess in the S/D feature.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart depicting an example method 100 of semiconductor fabrication including fabrication of multi-gate devices, in accordance with some embodiments.

FIGS. 2-3, 4A-4C, 5, 6A-6B, and 7-23, are schematic diagrams of a semiconductor structure at various stages of fabrication, in accordance with some embodiments.

FIG. 24 is a cross-sectional schematic view of an example semiconductor structure, in accordance with some embodiments.

FIG. 25 is a cross-sectional schematic view of an example semiconductor structure, in accordance with some embodiments.

FIG. 26 depicts a cross-sectional view of an example semiconductor structure with a magnified section, in accordance with some embodiments.

FIG. 27 depicts a cross-sectional view of an example semiconductor structure with a first silicide contact and a second silicide contact, in accordance with some embodiments.

FIG. 28 depicts a cross-sectional view of an example semiconductor structure with a first silicide contact and a second silicide contact, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

It should be understood that, although the terms first, second, third etc. may be used herein to describe various elements, components, regions, layers, portions and/or sections, these elements, components, regions, layers, portions, and/or sections should not be limited by these terms. These terms are only used to distinguish one element, component, region, layer, portion or section from another region, layer, or section. Thus, a first element, component, region, layer, portion, or section discussed below could be termed a second element, component, region, layer, portion, or section without departing from the teachings of the present disclosure.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

In certain embodiments herein, a “material layer” is a layer that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a layer that is a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of an aluminum layer and a layer of aluminum is a layer that is at least 50 wt. %, at least 60 wt. %, at least 75 wt. %, at least 90 wt. %, at least 95 wt. %, or at least 99 wt. % of aluminum.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

While the figures illustrate various embodiments of a semiconductor device, additional features may be added in the semiconductor device depicted in the Figures and some of the features described below can be replaced, modified, or eliminated in other embodiments of the semiconductor device.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

The present disclosure is generally related to semiconductor devices and the fabrication thereof, and in some cases to multi-gate devices. Multi-gate devices include those transistors whose gate structures are formed on at least two-sides of a channel region. These multi-gate devices may include an n-type metal-oxide-semiconductor device or a p-type metal-oxide-semiconductor multi-gate device. Specific examples herein may be presented and referred to herein as a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Presented herein are embodiments of devices that may have one or more channel regions (e.g., nanosheets) associated with a single, contiguous gate structure. One of ordinary skill may recognize other examples of semiconductor devices that may benefit from aspects of the present disclosure.

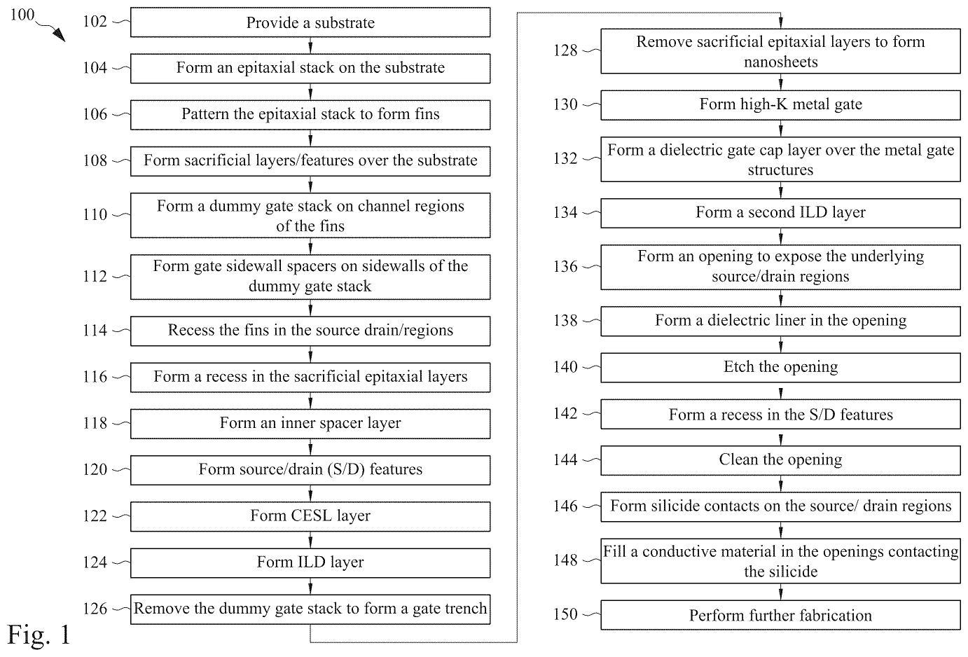

FIG. 1 is a flow chart depicting an example method 100 of semiconductor fabrication including fabrication of multi-gate devices, according to various aspects of the present disclosure. As used herein, the term “multi-gate device” is used to describe a device (e.g., a semiconductor transistor) that has at least some gate material disposed on multiple sides of at least one channel of the device. In some examples, the multi-gate device may be referred to as a GAA device having gate material disposed on four sides of at least one channel member of the device. The channel member may be referred to as “nano structure” or “nanosheet,” which is used herein to designate any material portion with nanoscale, or even microscale dimensions, and having an elongate shape, regardless of the cross-sectional shape of this portion. Thus, the term “nanostructure” or “nanosheet” as used herein designates both circular and substantially circular cross-section elongate material portions, and beam or bar-shaped material portions including for example a cylindrical in shape or substantially rectangular cross-section.

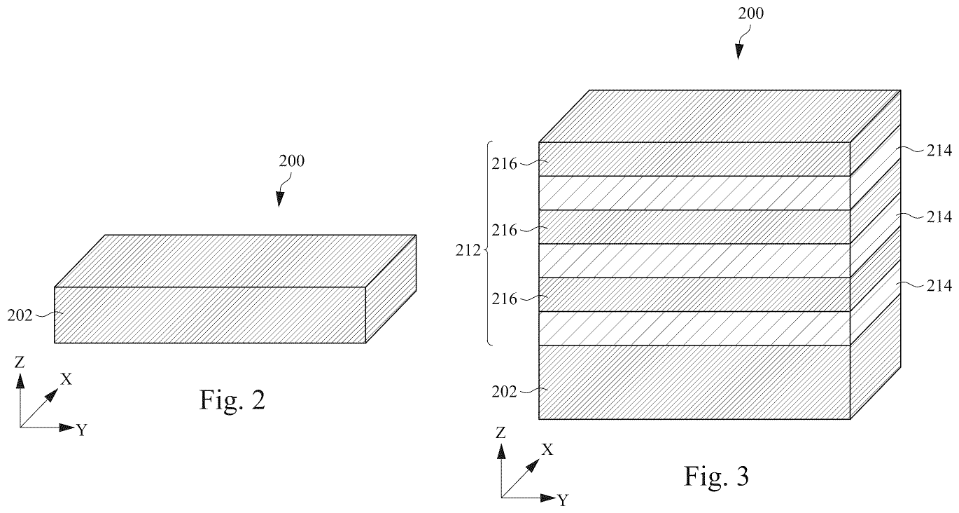

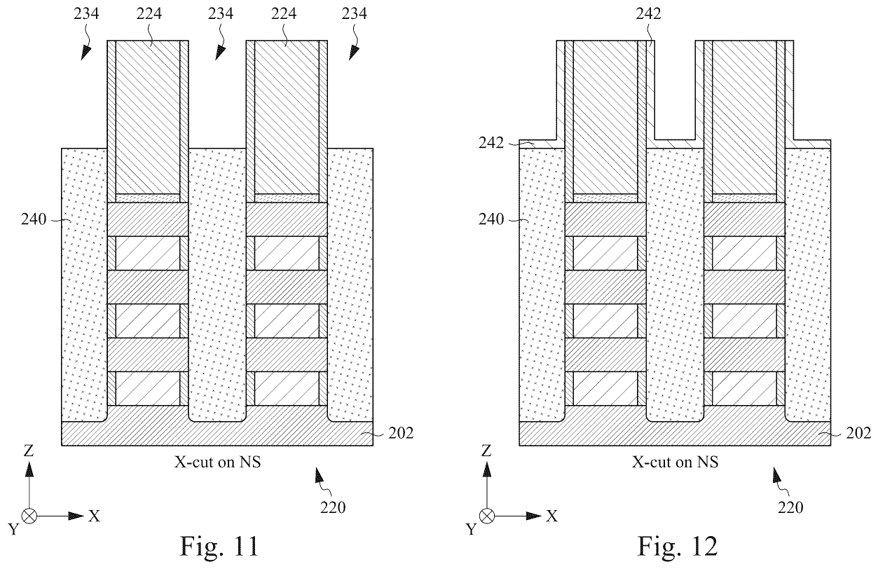

FIG. 1 is described in conjunction with FIGS. 2-3, 4A-4C, 5, 6A-6B, and 7-23, which illustrate a semiconductor device 200 or structure at various stages of fabrication in accordance with some embodiments. The method 100 is merely an example and is not intended to limit the present disclosure beyond what is explicitly recited in the claims. Additional steps may be provided before, during, and after method 100, and some of the steps described can be moved, replaced, or eliminated for additional embodiments of method 100. Additional features may be added in the semiconductor device 200 depicted in the figures, and some of the features described below can be replaced, modified, or eliminated in other embodiments.

As with the other method embodiments and exemplary devices discussed herein, it is understood that parts of the semiconductor devices may be fabricated by semiconductor technology process flow, and thus some processes are only briefly described herein. Further, the exemplary semiconductor devices may include various other devices and features, such as other types of devices such as additional transistors, bipolar junction transistors, resistors, capacitors, inductors, dials, fuses, and/or other logic devices, etc., but is simplified for better understanding of concepts of the present disclosure. In some embodiments, exemplary devices include a plurality of semiconductor devices (e.g., transistors), including PFETs, NFETs, etc., which may be interconnected. Moreover, it is noted that the process steps of method 100, include any descriptions given with reference to the figures, as with the remainder of the method and exemplary figures provided in this disclosure, are merely exemplary and are not intended to be limiting beyond what is specifically recited in the claims that follow.

FIGS. 2-3, 4A-4C, 5, 6A-6B, and 7-23, are schematic diagrams that illustrate an example semiconductor device structure at various stages of fabrication, in accordance with some embodiments. In some figures, some reference numbers of components or features illustrated therein may be omitted to avoid obscuring other components or features; this is for ease of depicting the figures.

At block 102, the example method 100 includes providing a substrate. Referring to the example of FIG. 2, in an embodiment of block 102, a substrate 202 is provided for forming a semiconductor device 200. In some embodiments, the substrate 202 may be a semiconductor substrate such as a silicon (Si) substrate. In some embodiments, the substrate 202 includes a single crystalline semiconductor layer on at least its surface portion. The substrate 202 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 202 may include a compound semiconductor and/or an alloy semiconductor. The substrate 202 may include various layers, including conductive or insulating layers formed on a semiconductor substrate. The substrate 202 may include various doping configurations depending on design requirements. For example, different doping profiles (e.g., n wells, p wells) may be formed on the substrate 202 in regions designed for different device types (e.g., n-type field effect transistors (NFET), p-type field effect transistors (PFET)). The suitable doping may include ion implantation of dopants and/or diffusion processes. The substrate 202 has isolation features (e.g., shallow trench isolation (STI) features) interposing the regions providing different device types. Further, the substrate 202 may be strained for performance enhancement, may include a silicon-on-insulator (SOI) structure, and/or have other suitable enhancement features.

At block 104, the example method 100 then includes forming an epitaxial stack over the substrate that includes a plurality of epitaxial layers. Referring to the example of FIG. 3, in an embodiment of block 104, an epitaxial stack 212 is formed over the substrate 202. The epitaxial stack 212 includes sacrificial epitaxial layers 214 of a first composition interposed by channel epitaxial layers 216 of a second composition. The first and second composition can be different. In an embodiment, the sacrificial epitaxial layers 214 are formed from SiGe and the channel epitaxial layers 216 are formed from silicon (Si). However, other embodiments are possible including those that provide for a first composition and a second composition having different oxidation rates and/or etch selectivity. In some embodiments, the sacrificial epitaxial layer 214 includes SiGe and the channel epitaxial layer 216 includes silicon (Si). However, other embodiments are possible including those that provide for a first composition and a second composition having different oxidation rates and/or etch selectivity. In some embodiments, the sacrificial epitaxial layer 214 includes SiGe and where the channel epitaxial layer 216 includes Si, the Si oxidation rate of the channel epitaxial layer 216 is less than the SiGe oxidation rate of the sacrificial epitaxial layer 214. It is noted that three (3) layers each of epitaxial layers 214 and 216 are illustrated in FIG. 3, which is for illustrative purposes only and not intended to be limiting beyond what is specifically recited in the claims. In various embodiments, any number of epitaxial layers can be formed in the epitaxial stack 212; the number of layers depending on the desired number of channel regions for the device 200. In some embodiments, the number of channel epitaxial layers 216 is between 2 and 10, such as 3, 4 or 5.

In some embodiments, the sacrificial epitaxial layer 214 has a thickness ranging from about 4 nm (nanometers) to about 12 nm. The sacrificial epitaxial layers 214 may be substantially uniform in thickness. In some embodiments, the channel epitaxial layer 216 has a thickness ranging from about 3 nm to about 6 nm. In some embodiments, the channel epitaxial layers 216 of the stack are substantially uniform in thickness.

As described in more detail below, the channel epitaxial layer 216 may serve as channel region(s) for a subsequently-formed multi-gate device and its thickness is chosen based on device performance considerations. The sacrificial epitaxial layer 214 may serve to reserve a spacing (or referred to as a gap) between adjacent channel region(s) for a subsequently-formed multi-gate device and its thickness is chosen based on device performance considerations.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxially grown layers, such as the channel epitaxial layers 216, include the same material as the substrate 202, such as silicon (Si). In some embodiments, the epitaxially grown layers 214 and 216 include a different material than the substrate 202. As stated above, in at least some examples, the sacrificial epitaxial layer 214 includes an epitaxially grown Si₁₋ₓGeₓ layer (e.g., x is about 25^{~}55%) and the channel epitaxial layer 216 includes an epitaxially grown Si layer. Alternatively, in some embodiments, either of the sacrificial epitaxial layers 214 and channel epitaxial layers 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the sacrificial epitaxial layers 214 and channel epitaxial layers 216 may be chosen based on providing differing oxidation and etch selectivity properties. In various embodiments, the epitaxial layers 214 and 216 are substantially dopant-free (i.e., having an extrinsic dopant concentration from about 0 cm⁻³ to about 1×10¹⁷ cm⁻³), where for example, no intentional doping is performed during the epitaxial growth process.

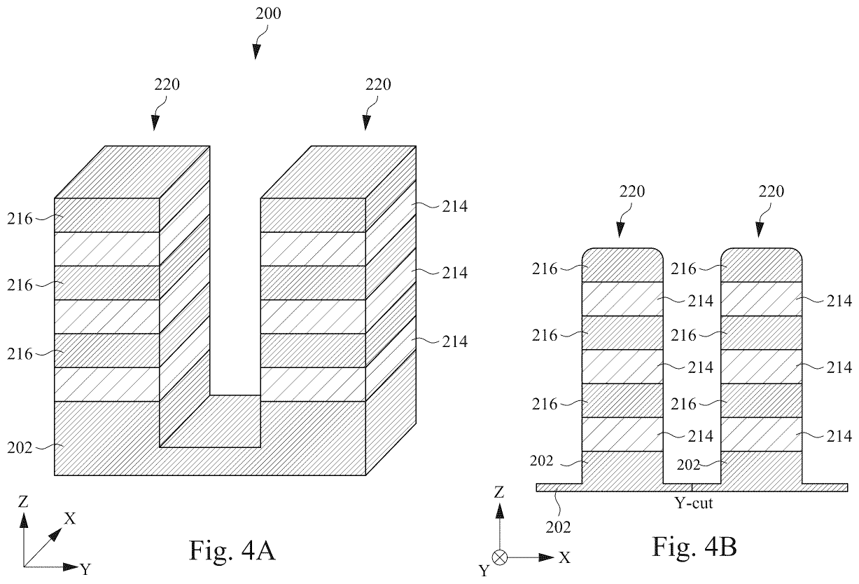

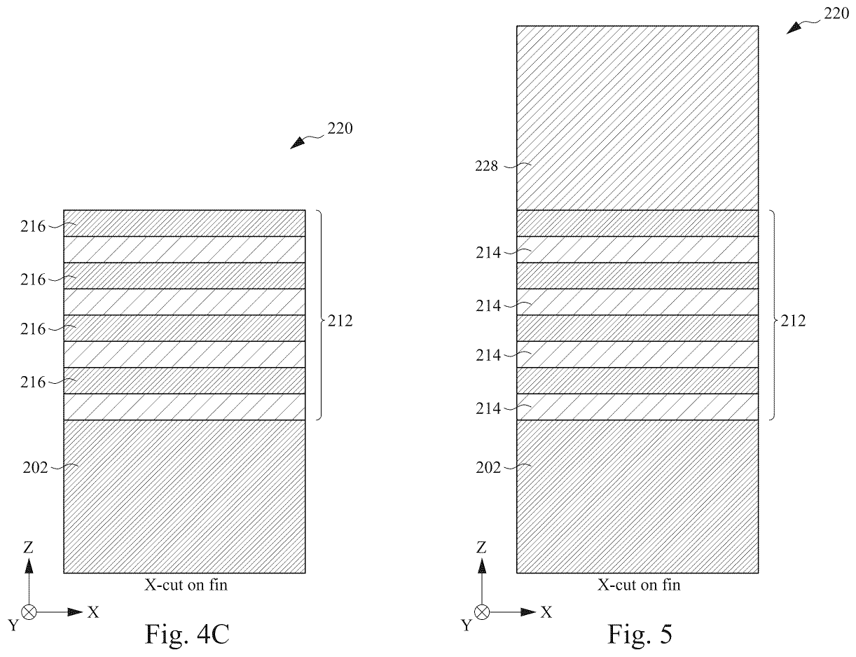

At block 106, the example method 100 includes patterning the epitaxial stack to form semiconductor fins (also referred to as fins). Referring to the example of FIGS. 4A, 4B, and 4C, in an embodiment of block 106, a plurality of fins 220 extending from the substrate 202 are formed. In various embodiments, each of the fins 220 includes an upper portion of the interleaved epitaxial layers 214 and 216 and a bottom portion protruding from the substrate 202.

The fins 220 may be fabricated using suitable processes including photolithography and etch processes. The photolithography process may include forming a photoresist layer over the substrate 202 (e.g., over the epitaxial stack 212), exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the substrate 202, and epitaxial stack 212 formed thereupon, while an etch process forms trenches in unprotected regions through masking layer(s) such as hard mask, thereby leaving the plurality of extending fins. The trenches may be etched using a dry etch (e.g., reactive ion etching), a wet etch, and/or other suitable processes. The trenches may be filled with dielectric material forming, for example, shallow trench isolation features interposing the fins.

At block 108, the example method 100 includes forming one or more sacrificial layers/features over the substrate. Referring to the example of FIG. 5, in an embodiment of block 108, a sacrificial gate dielectric layer (not shown) is blanket deposited over a stop layer 222, which is formed over the fin 220, which is formed over the substrate 202. A sacrificial gate electrode layer 228 is then blanket deposited on the sacrificial gate dielectric layer and over the substrate 202. The sacrificial gate electrode layer 228 includes silicon such as polycrystalline silicon or amorphous silicon. The thickness of the sacrificial gate dielectric layer is in a range from about 1 nm to about 5 nm in some embodiments. The thickness of the sacrificial gate electrode layer is in a range from about 100 nm to about 200 nm in some embodiments. In some embodiments, the sacrificial gate electrode layer is subjected to a planarization operation. The sacrificial gate dielectric layer and the sacrificial gate electrode layer 228 may be deposited using CVD, including LPCVD and PECVD, PVD, ALD, or other suitable processes.

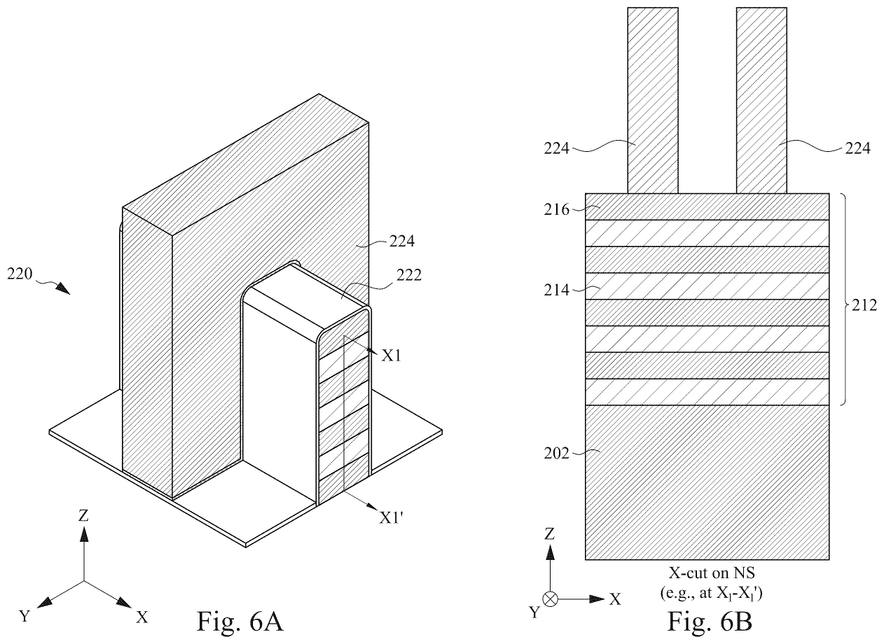

At block 110, the example method 100 includes patterning the one or more sacrificial layers/features to form a dummy gate structure on channel regions of the fins. Referring to the example of FIGS. 6A and 6B, in an embodiment of block 110, a sacrificial gate structure 224 is formed over portions of the fins 220 which are to be channel regions. The sacrificial gate structure 224 defines the channel regions of a GAA device. The sacrificial gate structure 224 includes a sacrificial gate dielectric layer and a sacrificial gate electrode layer 228. The sacrificial gate structure 224 is formed by forming a mask layer over the sacrificial gate electrode layer. The mask layer may include a pad silicon oxide layer and a silicon nitride mask layer. Subsequently, a patterning operation is performed on the mask layer and sacrificial gate dielectric and electrode layers are patterned into the sacrificial gate structure 224. By patterning the sacrificial gate structure 224, the fins 220 are partially exposed on opposite sides of the sacrificial gate structure 224, thereby defining source/drain (S/D) regions. In this disclosure, a source and a drain are interchangeably used, and the structures thereof are substantially the same.

The sacrificial gate structure 224 is subsequently removed as discussed with reference to block 132 of the method 100 and will be replaced by a final gate stack at a subsequent processing stage of the device 200. In particular, the sacrificial gate structure 224 is replaced at a later processing stage by a high-K dielectric layer (HK) and metal gate electrode (MG) as discussed below.

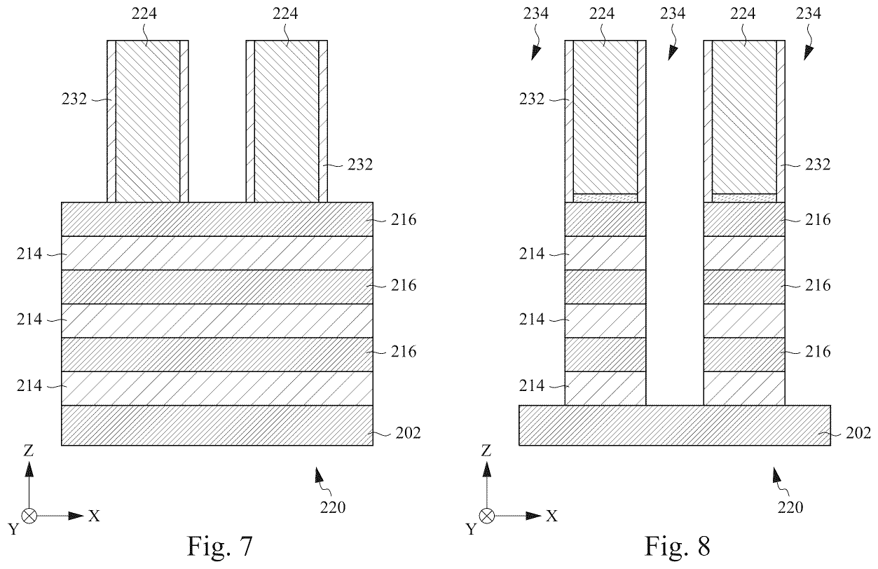

At block 112, the example method 100 includes forming gate sidewall spacers on sidewalls of the sacrificial gate structure. Referring to the example of FIG. 7, in an embodiment of block 112, gate sidewall spacers 232 are formed on sidewalls of the sacrificial gate structure 224. In various embodiments, the gate sidewall spacers 232 may include a dielectric material such as silicon oxide (SiOₓ), silicon nitride (SiN), silicon carbide (SIC), silicon oxynitride (SiON), SiCN films, silicon oxycarbide (SiOC), Silicon oxycarbonitride (SiOCN) films, and/or combinations thereof. In some embodiments, the gate sidewall spacers 232 include multiple layers, such as main spacer walls, liner layers, and the like. By way of example, the gate sidewall spacers 232 may be formed by depositing a dielectric material layer over the sacrificial gate structure 224 using processes such as, a CVD process, a sub atmospheric CVD (SACVD) process, a flowable CVD process, an ALD process, a PVD process, or other suitable process. In some embodiments, the deposition of the dielectric material layer is followed by an etching-back (e.g., anisotropically) process to expose portions of the fin 220 adjacent to and not covered by the sacrificial gate structure 224 (e.g., S/D regions). The dielectric material layer may remain on the sidewalls of the sacrificial gate structure 224 as gate sidewall spacers 232. In some embodiments, the etching-back process may include a wet etch process, a dry etch process, a multiple-step etch process, and/or a combination thereof. The gate sidewall spacers 232 may have a thickness ranging from about 5 nm to about 20 nm.

At block 114, the example method includes recessing the fins in the source drain/regions. Referring to the example of FIG. 8, in an embodiment of block 116, the fin 220 is recessed in the source drain/regions. The stacked epitaxial layers 214 and 216 are etched down at the S/D regions to form a recess 234. In various embodiments, the recessing is performed by a suitable etching process, such as a dry etching process, a wet etching process, or an RIE process. Dry etching may be implemented using an etchant including a bromine-containing gas (e.g., HBr and/or CHBR3), a fluorine-containing gas (e.g., CF4, SF6, CH2F2, CHF3, and/or C2F6), other suitable gases, or combinations thereof.

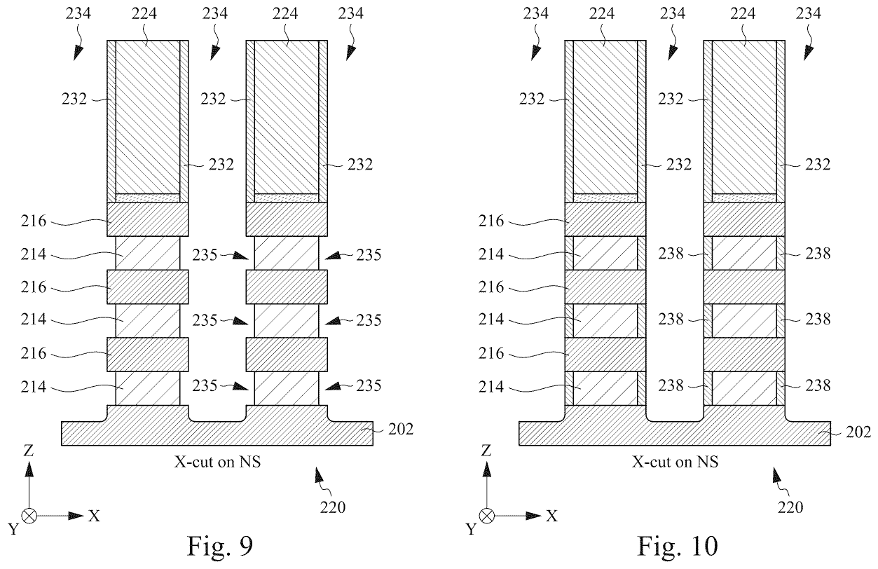

At block 116, the example method 100 includes forming a recess in the sacrificial epitaxial layers (e.g., SiGe) of the epitaxial stack. Referring to the example of FIG. 9, in an embodiment of block 116, the sacrificial epitaxial layers 214 have been etched back forming sacrificial epitaxial layer recesses 235 bounded on the top and bottom by channel epitaxial layers 216 and laterally by the recessed sacrificial epitaxial layers 214. The sacrificial epitaxial layers 214 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. Alternatively, at block 118 lateral ends of the sacrificial epitaxial layers 214 that are exposed in the recess 234 may be selectively oxidized to increase the etch selectivity between the epitaxial layers 214 and 216. In some examples, the oxidation process may be performed by exposing the device 200 to a wet oxidation process, a dry oxidation process, or a combination thereof.

At block 118, the example method 100 Includes forming an inner spacer layer in the sacrificial epitaxial layer recesses. Forming the inner spacer layer may include depositing inner spacer material of a first material type in the sacrificial epitaxial layer recesses, and trimming the inner spacer layers (e.g., via etching operations). Referring to the example of FIG. 10, in an embodiment of block 118, inner spacer layers 238 are formed in the sacrificial epitaxial layer recesses 235. The inner spacer layers 238 may be formed from may be formed from silicon oxides, silicon nitrides, silicon carbides, silicon carbide nitride, silicon oxide carbide, silicon carbide oxynitride, and/or other suitable dielectric materials. In some embodiments, the inner spacer layer 238 is deposited as a conformal layer. The inner spacer layers 238 can be formed by ALD or any other suitable method. In various embodiments, the inner spacer layers 238 are formed from the same material as the gate sidewall spacers 232. In various embodiments, the gate sidewall spacers 232 and the inner spacer layers 238 are formed from SiOCN.

At block 120, the example method 100 includes forming source/drain (S/D) features. Forming the S/D features may involve depositing pure silicon in the recess 234 in the source drain/regions. In various embodiments, recessing the fins in the S/D regions may involve over etching the fins in the S/D regions wherein some of the substrate 202 below the height level of the bottom sacrificial epitaxial layer 214 is removed to prevent SiGe residue. Pure Si may be deposited in the recess 234 to raise the height of the substrate 202 below the recess 234 to the height level of the bottom sacrificial epitaxial layer 214.

Forming the S/D features may also involve depositing AlOx over the NMOS S/D regions and the PMOS S/D regions, patterning the PMOS S/D regions to remove the AlOx over the PMOS S/D regions, and depositing PMOS material for forming epitaxial S/D features in the PMOS S/D regions. Following forming the epitaxial S/D features in the PMOS S/D regions, forming the S/D features may involve depositing AlOx over the PMOS S/D regions, patterning the NMOS S/D regions to remove the AlOx over the NMOS S/D regions, and depositing NMOS material for forming epitaxial S/D features in the NMOS S/D regions.

Referring to the example of FIG. 12, in an embodiment of block 122, epitaxial S/D features 240 are formed in recess 234. In some embodiments, the epitaxial S/D features 240 include silicon for NFETs and SiGe for PFETs. In some embodiments, the epitaxial S/D features 240 are formed by an epitaxial growth method using CVD, ALD, or molecular beam epitaxy (MBE). The epitaxial S/D features 240 are formed in contact with the channel epitaxial layers 216 and separated from the sacrificial epitaxial layers 214 by the inner spacer layers 238.

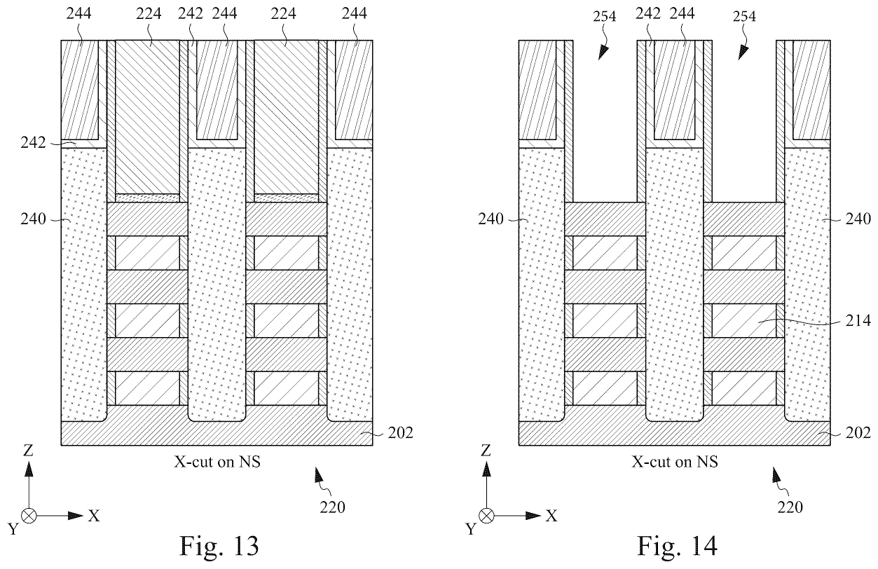

At block 122, the example method 100 includes forming a CESL layer. Referring to the example of FIG. 13, in an embodiment of block 124, a CESL layer 242 is formed over the S/D features 240. The CESL layer 242 may comprise silicon nitride, silicon oxynitride, silicon nitride with oxygen (O) or carbon (C) elements, and/or other materials; and may be formed by CVD, PVD (physical vapor deposition), ALD, or other suitable methods. In various embodiments, the CESL layer 242 is formed from SiN.

At block 124, the example method 100 includes forming an ILD layer. Referring to the example of FIG. 13, in an embodiment of block 124, a first interlayer dielectric (ILD0) layer 244 is formed over the CESL layer 242. The ILD0 layer 244 may comprise tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD0 layer 244 may be formed by PECVD, flowable CVD (FCVD), or other suitable methods. In some embodiments, forming the ILD0 layer 244 further includes performing a CMP process to planarize a top surface of the device 200, such that the top surfaces of the sacrificial gate structure 224 are exposed.

At block 126, the example method 100 includes removing the dummy gate stack to form a gate trench. Referring to the example of FIG. 14, in an embodiment of block 126, the sacrificial gate structure 224 has been removed to form a gate trench 254. The gate trench 254 exposes the fin 220 in the channel region(s). The ILD0 layer 244 and the CESL layer 242 protects the epitaxial S/D features 240 during the removal of the sacrificial gate structure 224. The sacrificial gate structure 224 can be removed using plasma dry etching and/or wet etching. When the sacrificial gate electrode layer is polysilicon and the ILD0 layer 244 is an oxide, a wet etchant such as a TMAH solution can be used to selectively remove the sacrificial gate electrode layer. The sacrificial gate dielectric layer is thereafter removed using plasma dry etching and/or wet etching.

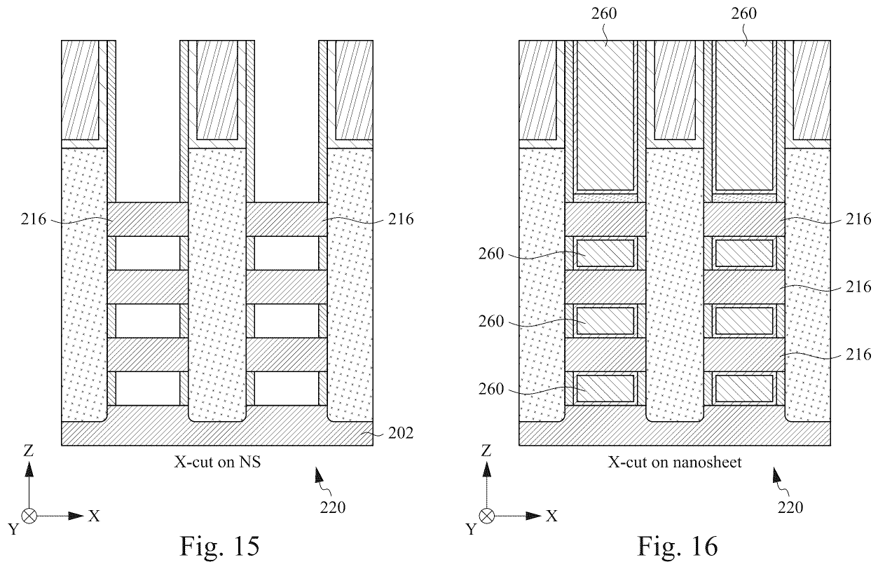

At block 128, the example method 100 includes removing the sacrificial epitaxial layers to form nanosheets. Referring to the example of FIG. 15, in an embodiment of block 128, sacrificial epitaxial layers 214 have been removed thereby releasing channel members from the channel region of the GAA device. In the illustrated embodiment, channel members are channel epitaxial layers 216 in the form of nanosheets. In various embodiments, the channel epitaxial layers 216 include silicon, and the sacrificial epitaxial layers 214 include silicon germanium. In various embodiments, the plurality of sacrificial epitaxial layers 214 were selectively removed via a selective removal process that included oxidizing the plurality of sacrificial epitaxial layers 214 using a suitable oxidizer, such as ozone. Thereafter, the oxidized sacrificial epitaxial layers 214 were selectively removed via a dry etching process, for example, by applying an HCl gas at a temperature of about 500 degrees Celsius to about 700 degrees Celsius, or applying a gas mixture of CF₄, SF₆, and CHF₃.

At block 130, the example method 100 includes forming high-K metal gate structures. Referring to the example of FIG. 16, in an embodiment of block 130, a gate structure 260 is formed. In various embodiments, the gate structure 260 is the gate of a multi-gate transistor. In various embodiments, the gate structure 260 is a high-K metal gate stack, however other compositions are possible. In various embodiments the high-K metal gate stack includes a gate dielectric layer that includes an interfacial layer and a high-k dielectric layer. The high-k dielectric layer wraps each of the nanosheets 216, and the interfacial layer is interposed between the high-k dielectric layer and the nanosheets 216. The interfacial layer may include a dielectric material such as silicon oxide (SiO₂) or silicon oxynitride (SiON), and may be formed by chemical oxidation, thermal oxidation, atomic layer deposition (ALD), CVD, and/or other suitable methods. The high-k dielectric layer may include hafnium oxide (HfO₂), hafnium silicon oxide (HfSiO), hafnium silicon oxynitride (HfSiON), hafnium tantalum oxide (HMO), hafnium titanium oxide (HfTiO), hafnium zirconium oxide (HfZrO), other suitable high-k dielectric materials, and/or combinations thereof. The high-k material may further be selected from metal oxides, metal nitrides, metal silicates, transition metal-oxides, transition metal-nitrides, transition metal-silicates, oxynitrides of metals, metal aluminates, zirconium silicate, zirconium aluminate, silicon oxide, silicon nitride, silicon oxynitride, zirconium oxide, titanium oxide, aluminum oxide, hafnium dioxide-alumina (HfO₂—Al₂O₃) alloy, other suitable materials, and/or combinations thereof. The high-k dielectric layer may be formed by any suitable process, such as atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, other suitable processes, and/or combinations thereof. In one embodiment, the gate dielectric layer is formed using a highly conformal deposition process such as ALD in order to ensure the formation of a gate dielectric layer having a uniform thickness around each channel layer. The high-K metal gate structures may include additional material layers.

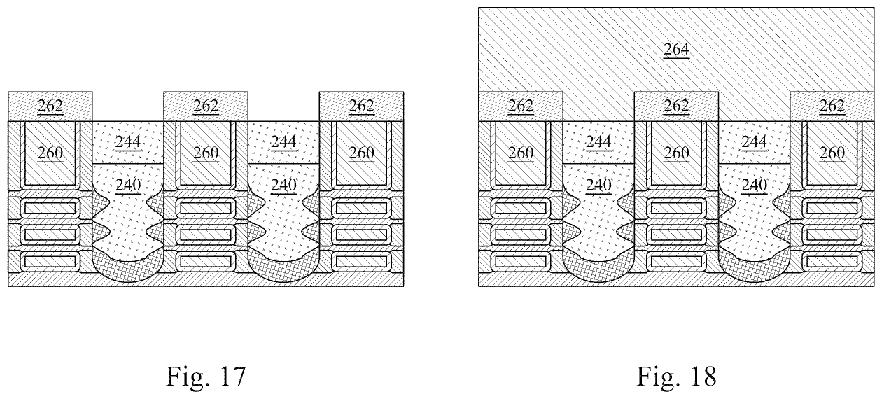

At block 132, the example method 100 includes forming a dielectric gate cap layer over the metal gate structures. The dielectric gate cap layer may be formed by a selective deposition of a dielectric, such as SiN over the metal gate structures, but not the surrounding ILD0 layer. The dielectric gate cap layer can function to protect the gate structure during subsequent metal drain (MD) formation. The dielectric gate cap layer may be formed using a type of area-selective deposition process wherein deposition occurs at selected areas. Referring to the example of FIG. 17, in an embodiment of block 132, the example semiconductor structure includes a dielectric gate cap layer 262 deposited over the gate structure 260. The dielectric gate cap layer 262, however, is not formed over the ILD0 layer 244.

At block 134, the example method 100 includes forming a second ILD layer (ILD1 layer) over the ILD0 layer and the dielectric gate cap layer. Referring to the example of FIG. 18, in an embodiment of block 134, the example semiconductor structure includes an ILD1 layer 264 formed over the ILD0 layer 244 and the dielectric gate cap layer 262. The ILD1 layer 264 may include or be a material such as silicon nitride (SiN), although other suitable materials, such as silicon oxide (SiO₂), aluminum oxide (AIO), silicon oxycarbide (SiOC), silicon carbon (SiC), zirconium nitride (ZrN), zirconium oxide (ZrO), combinations of these, or the like, may also be utilized. The ILD1 layer 264 may be deposited using a deposition process such as plasma enhanced atomic layer deposition (PEALD), thermal atomic layer deposition (thermal ALD), plasma enhanced chemical vapor deposition (PECVD), or others. Any suitable deposition process and process conditions may be utilized.

At block 136, the example method 100 includes forming an opening in the ILD0 layer and the ILD1 layer that expose the underlying source/drain regions. Forming an opening may include forming a patterned mask that exposes a portion of the ILD1 layer and selectively removing the exposed portion of the ILD1 layer and the underlying ILD0 layer to form the opening. In various embodiments, the patterned mask may include a photo resist layer. The patterned mask may be formed by photoresist coating (e.g., spin-on coating), soft baking, mask aligning, exposure, post-exposure baking, developing the photoresist, rinsing, drying (e.g., hard baking), and/or combinations thereof. In some other embodiments, various imaging enhancement layers may be formed under photo resist layer to enhance the pattern transfer. The imaging enhancement layer may comprise a tri-layer including a bottom organic layer, a middle inorganic layer and a top organic layer. The imaging enhancement layer may also include an anti-reflective coating (ARC) material, a polymer layer, an oxide derived from TEOS (tetraethylorthosilicate), silicon oxide, or a Si-containing anti-reflective coating (ARC) material, such as a 42% Si-containing ARC layer. In yet some other embodiments, the patterned mask layer includes a hard mask layer. The hard mask layer includes an oxide material, silicon nitride, silicon oxynitride, an amorphous carbon material, silicon carbide or tetraethylorthosilicate (TEOS).

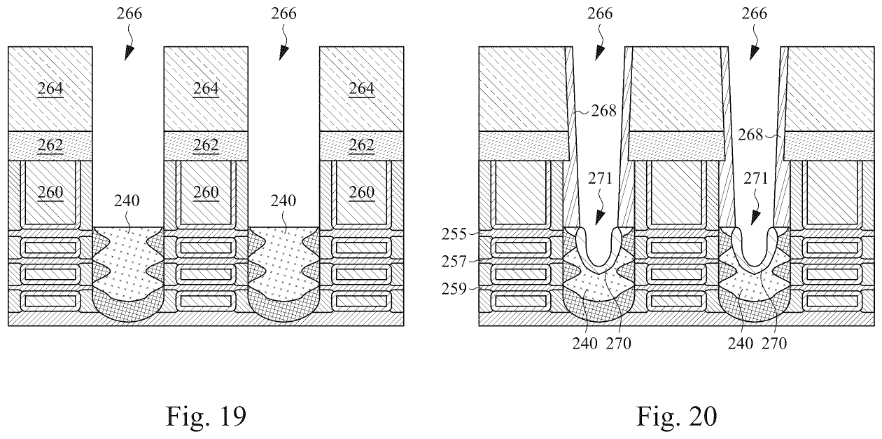

Referring to the example of FIG. 19, in an embodiment of block 136, the example semiconductor structure includes an opening 266 in the ILD1 layer 264 and the ILD0 layer 244 that expose the underlying source/drain features 240. The ILD1 layer 264 and ILD0 layer 244 are selectively removed to create the opening 266 to expose the S/D features 240. The exposed portions of the ILD1 layer 264 and ILD0 layer 244 can be removed by suitable etching process, such as wet etching, dry etching, or combination thereof. The dielectric gate cap layer 262 protects the gate structure 260 during etching operations to expose the S/D features 240.

At block 138, the example method 100 includes forming a dielectric liner in the opening that exposes the S/D regions. The dielectric liner may be formed from a material such as SiN and may be formed by any suitable process, such as atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, other suitable processes, and/or combinations thereof.

At block 140, the example method 100 includes etching the opening to remove a portion of the dielectric liner on sidewalls of the opening and the dielectric liner on the bottom of the opening. In various embodiments, the etching is performed using a wet etch process.

At block 142, the example method 100 includes increasing the depth of the opening into the S/D features to a depth below at least the first nanosheet by forming a recess in the S/D features. In various embodiments the depth of the opening is increased using a dry etch process that leaves an oxide-like byproduct on sidewalls of the S/D features in the recess. In various embodiments, the dry etching process includes plasma etching using a gas mixture including CH₄, Ar, HBr, O₂, Cl₂, BCl₃, and/or N₂ gas.

Referring to the example of FIG. 20, in an embodiment after block 142, the opening 266 in the example semiconductor structure has been extended into a recess 271 in the S/D features 240. The example semiconductor structure includes a first nanosheet 255, a second nanosheet 257, and a third nanosheet 259. The opening 266 extends to a depth below at least the first nanosheet 255. A dielectric liner 268 is formed on sidewalls of the opening 266, and an oxide-like byproduct 270 is formed on sidewalls and the bottom of the opening 266 in the S/D features 240.

At block 144, the example method 100 includes cleaning the opening, which removes oxide-like byproduct left from the dry etch. Because of the high wet etching selectivity of the dry etching byproduct to SiP/SiGe of the S/D features 240 and high wet etching selectivity of the dry etching byproduct to SiN of the dielectric liner 268, wet etching can be used to remove the oxide-like byproduct left from the dry etch. In various embodiments, the wet etching can include using a fluorine derivative acid, such as HF, HBF₄, NH₄BF₄, or others at a concentration range from 200 ppm to 10 wt %.

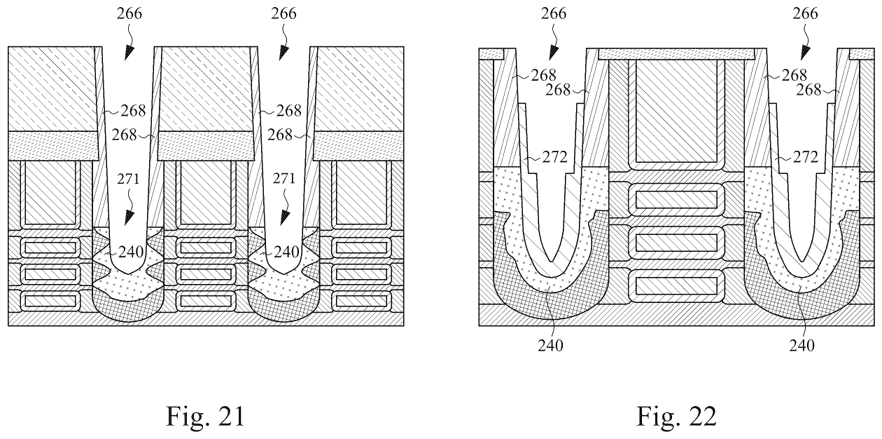

The forming the dielectric liner (block 138), etching the opening (block 140), increasing the opening using the dry etch process (block 142), and the cleaning the opening (block 140) results in creating a tapered profile in the S/D features that facilitates subsequent silicide formation and metal deposition. Referring to the example of FIG. 21, in an embodiment of block 144, the oxide-like byproduct has been removed, and the opening 266 has a tapered profile wherein the width of the opening is wider at the top of the opening and narrows as the opening approaches the S/D features 240.

At block 146, the example method 100 includes forming silicide contacts on the source/drain regions that have been exposed. Because the S/D features for n-type FETs may comprise SiP, the S/D features for p-type FETs may comprise SiGe, and the dielectric liner 268 may comprise SiN, Silicide contacts can be formed contacting the Si of the dielectric liner 268 and the S/D features 240. The silicide contact may comprise titanium (e.g., titanium silicide (TiSi)) in order to reduce the Schottky barrier height of the contact. However, other metals, such as nickel (e.g., nickel silicide (NiSi)), cobalt (e.g., cobalt silicide (CoSi)), copper (e.g., copper silicide (CuSi)), and others, may also be used. A silicidation may be performed by blanket deposition of an appropriate metal layer, followed by an annealing step which causes the metal to react with the underlying exposed silicon of the source/drain regions and silicon of the dielectric liner. Referring to the example of FIG. 22, in an embodiment after completion of block 146, the semiconductor structure includes silicide contacts 272 on the S/D features 240 and a portion of the dielectric liner 268. In various embodiments, the thickness of the silicide contacts 272 ranges from about 3 nm to about 10 nm. Forming part of the silicide contacts 272 against the dielectric liner 268 can increase the contact area of the silicide contacts 272. The tapered nature of the opening 266 in the S/D features 240 also allow for an increase in contact area of the silicide contacts 272.

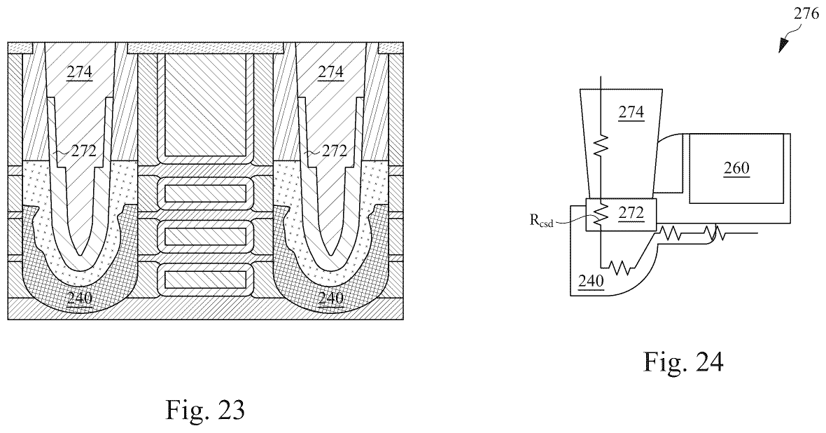

At block 148, the example method 100 includes filling a conductive material in the openings contacting the silicide in the source/drain regions to form source/drain contacts (also referred to herein as metal drain (MD) contacts). The source/drain contact may comprise one or more layers. For example, in some embodiments, the source/drain contact comprise a liner and a metal fill material (not individually shown) deposited by, for example, CVD, ALD, electroless deposition (ELD), PVD, electroplating, or another deposition technique. The liner, such as a diffusion barrier layer, an adhesion layer, or the like, may include titanium, titanium nitride, tantalum, tantalum nitride, or the like. The conductive material may be copper, a copper alloy, silver, gold, tungsten, cobalt, aluminum, ruthenium, nickel, or the like. A planarization process, such as a CMP, may be performed to remove excess liner and conductive material. The remaining liner and conductive material form the source/drain contact in the opening. Referring to the example of FIG. 23, in an embodiment after completion of block 148, the semiconductor structure includes a conductive material filling the openings 266 (shown in FIG. 22) and contacting the source/drain features 240 through the silicide contacts 272 to form source/drain contacts (MD 274).

At block 150, the example method 100 includes performing further fabrication. A semiconductor device may undergo further processing to form various features and regions known in the art. For example, subsequent processing may include filling the opening over the source/drain regions with ILD1 material to fill in the ILD1 layer and forming one or more intermetal dielectric (IMD) layers over the ILD1 layer. Each IMD layer may include an etch stop layer (ESL) above the underlying layer and an ILD layer above the ESL. The ESL may be deposited using one or more low temperature deposition processes such as chemical vapor deposition, physical vapor deposition, or atomic layer deposition. Subsequent processing may also include forming contact openings, contact metal, as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 100, and some process steps described above may be replaced or eliminated in accordance with various embodiments of the method 100.

Silicide has been a preferred material for contact to the source/drain (S/D) regions of silicon FET devices for many years. Silicide contacts can offer a higher device performance owing to lower parasitic resistance. However, shrinking transistor dimensions can cause an increase in contact resistance. Ultralow contact resistance of metal-silicon contacts can lead to high performance.

The tapered nature of the silicide contacts 272 allows for lower silicide contact resistance. FIG. 24 depicts a cross-sectional schematic view of an example semiconductor structure 276. The example semiconductor structure 276 includes a gate structure 260, S/D features 240, a silicide contacts 272, and a MD 274. The silicide contacts 272 have a silicide contact resistance (R_{csd}) that is one component of transistor resistance. The silicide contact resistance (R_{csd}) is equal to the silicide resistivity (ρ_{csd}) divided by the area of the silicide contact, i.e.,

$${R}_{csd} = \frac{Pcsd}{A} .$$

The area gain attained by the tapered silicide contacts 272 results in decreased silicide contact resistance. As the silicon contact area of the silicide contacts 272 increases, the Silicide contact resistance (R_{csd}) decreases. The results in improved device performance.

In various embodiments, low metal-silicon contact resistance is achieved by an enlarged silicide area. The low contact resistance provides low parasitic resistance and consequently a ring oscillator speed boost and better device performance, such as decreased power consumption. The depth of the silicide contact 272 in the S/D features can be tuned without negatively affecting the fabrication process.

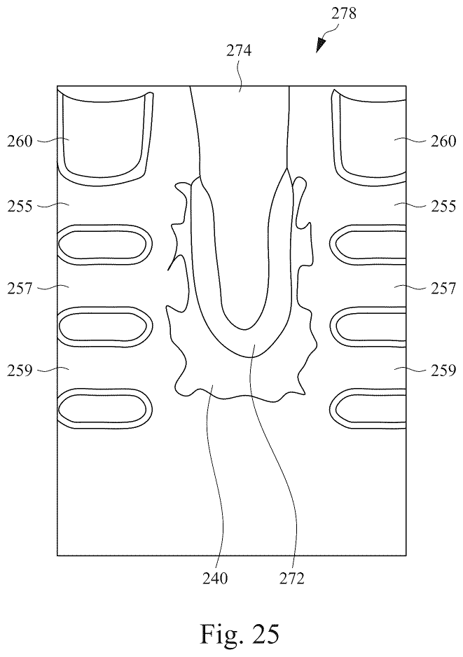

FIG. 25 depicts a cross-sectional view of an example semiconductor structure 278. Illustrated are a gate structure 260, a first nanosheet 255, a second nanosheet 257, and a third nanosheet 259. Also illustrated are S/D features 240, silicide contacts 272, and MD 274. The MD 274 has a tapered profile that provides increased contact area for lower silicide contact resistance. The silicide contacts 272 extend to a depth below the first nanosheet 255.

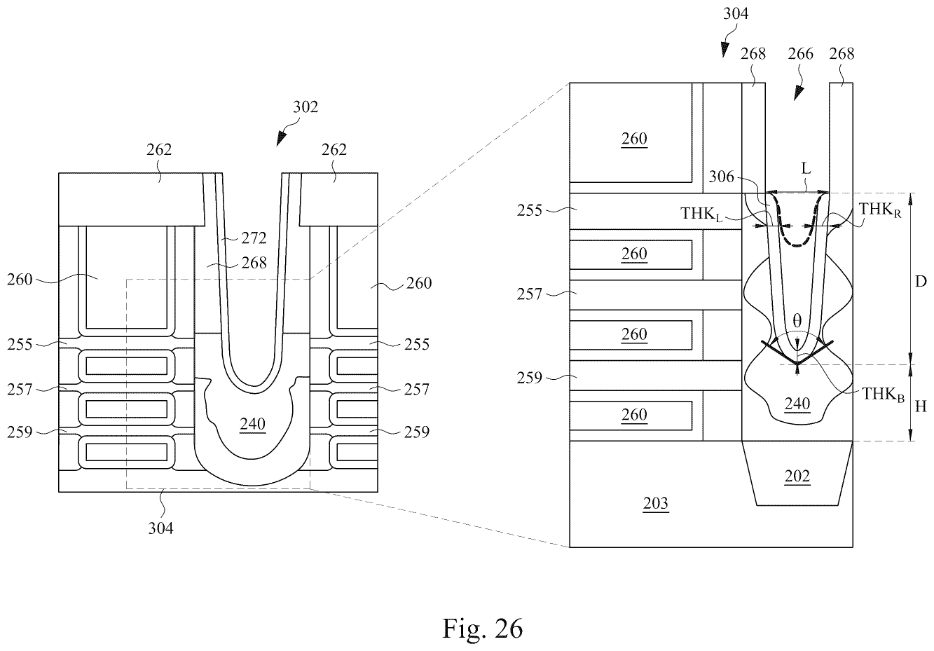

FIG. 26 depicts a cross-sectional view of an example semiconductor structure 302 with a magnified section 304. Illustrated are a substrate 202, shallow trench isolation (STI 203), a gate structure 260, a dielectric gate cap layer 262, a first nanosheet 255, a second nanosheet 257, a third nanosheet 259, S/D features 240, a dielectric liner 268, a silicide contact 306, and an opening 266 into which a MD is to be formed. FIG. 24 illustrates example dimensions of various components of the silicide contact 306.

The silicide contact 306 has a tapered profile. The tapered profile extends to a depth below the first nanosheet 255 to achieve low resistance. The silicide contact 306 has a workable depth (D) measured at a height at a top of the first nanosheet 255 to the bottom of the silicide contact 306 and a height (H) in relation to STI 203 below a bottom nanosheet (e.g., third nanosheet 259) to a bottom of the silicide contact. In various embodiments, the workable depth (D) is between about 14 nm to about 37 nm (e.g., 14 nm≤D≤37 nm). If the depth (D) is too shallow, the benefits of enlargement of the silicide contact 306 cannot be obtained. If the depth (D) is too deep, EPI damage to the S/D feature 240 may occur resulting in source/drain damage. Controlling the range of depth (D) to 14 nm≤D≤37 nm can allow the benefits of enlargement of the silicide contact 306 to be achieved. In various embodiments, the height (H) of silicide contacts 272 is between about 6 nm to about 28 nm (e.g., 6 nm≤H≤28 nm). The workable depth (D) and the height (H) have an inverse relationship—a deeper D results in a smaller H. In other words, the deeper the D, the shorter the H, and vice versa. Controlling the range of height (6 nm≤H≤28 nm) can avoid EPI damage and allow the silicide contact area to be enlarged.

The silicide contact 306 has a critical dimension (CD) measured across the silicide contact at a height at the top of the first nanosheet 255. In various embodiments, the length (L) of the CD is between about 8 nm to about 16 nm (e.g., 8 nm≤L≤16 nm). The length (L) represents the length of the opening CD used for plasma etch in the process. If the opening CD (L) is too small, etching cannot proceed smoothly and reach the target depth (D). If the opening CD (L) is too large, EPI damage may occur during etching. When L≤10 nm, D≤17 nm (to get deeper depth, (L) must ≥10 nm). In various embodiments, the silicide contact 306 has an effective aspect ratio (D/L) that is between about 0.8 to about 4 (e.g., 0.8≤D/L≤4). D and L have a certain degree of correlation. It can be easier to achieve a deeper depth (D) with a larger opening CD (L). The effective aspect ratio (D/L) represents the range within which the process is workable, including plasma dry etching and a post-etch wet cleaning process.

The silicide contact 306 has an effective area of taper profile (A). In various embodiments, the effective area of taper profile (A) is between about 72 nm² to about 280 nm² (e.g., 72 nm²≤A≤280 nm²).

The silicide contact 306 has a tangent angle of the bottom taper profile (θ). In various embodiments, the tangent angle of the bottom taper profile (θ), is between about 95° to about 135° (e.g., 95°≤θ≤135°). The smaller the angle (θ), the better. However, maintaining performance without damaging the EPI makes can make it difficult to achieve a very small angle (<95°). If the angle (θ) is greater than 135°, there is a risk of EPI damage.

The silicide contact 306 has a left-side sidewall thickness (THKL), a right-side sidewall thickness (THKR), and a bottom Silicide thickness (THKB). In various embodiments, each of the left-side sidewall thickness (THKL) and the right-side sidewall thickness (THKR) are in a range of approximately 2 nm to approximately 4.5 nm. In various embodiments, the thickness difference between the left-side sidewall thickness (THKL) and the right-side sidewall thickness (THKR) is less than 1 nm (e.g., |THKL−THKR|<1 nm). In various embodiments, the bottom Silicide thickness (THKB) is in the range of approximately 4 nm to approximately 6.5 nm. Silicide is composed of silicon and metal, with conductive properties that are between those of metal and silicon. It serves as a connection layer at the interface between metal and semiconductor, with a primary purpose of reducing resistance. The silicide on the sidewall and bottom form simultaneously, so their thicknesses are directly correlated: the thicker the bottom, the thicker the sidewall. If the measured sidewall silicide thickness (THKL and/or THKR) is too thick, the filling material (e.g., metal or BARC, etc.) in the process following silicide growth may not be applied properly, or seams may form. This might lead to high resistance or the risk of metal gate to contact leakage. If the silicide at the bottom (THKB) is too thick, it can result in an excessively high metal ratio, potentially leading to the risk of high resistance. If the silicide at the bottom (THKB) is too thin, the silicide is less likely to serve as a good connection layer leading to increased resistance.

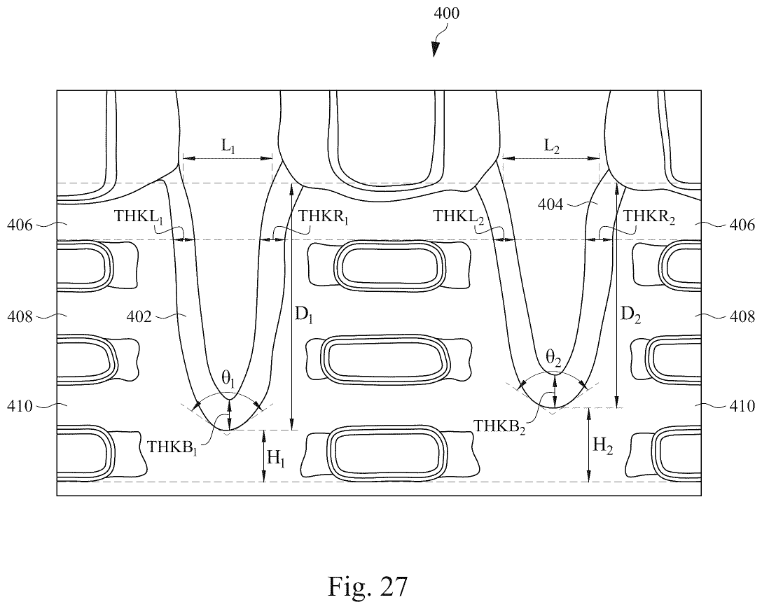

FIG. 27 depicts a cross-sectional view of an example semiconductor structure 400 with a first silicide contact 402 and a second silicide contact 404. Each of the first silicide contact 402 and the second silicide contact 404 has a tapered profile. Each of the first silicide contact 402 and the second silicide contact 404 extends below a second nanosheet 408.

The first silicide contact 402 has a workable depth (D₁) measured at a height from the top of a first nanosheet 406 to the bottom of the silicide contact in the range of approximately 14 nm to approximately 37 nm (e.g., 35.82 nm). The first silicide contact 402 has a height (H₁) in relation to STI below a bottom nanosheet 410 to the bottom of the first silicide contact 402 in the range of approximately 6 nm to approximately 28 nm (e.g., 8.42 nm). The first silicide contact 402 has a length (L₁) across the silicide contact measured at a height at a top of the first nanosheet 406 in the range of approximately 8 nm to approximately 16 nm (e.g., 13.03 nm). The first silicide contact 402 has a tangent angle of a bottom taper profile (θ₁) of the silicide contact in the range of approximately 95° to approximately 135° (e.g., 126.38°). The first silicide contact 402 has a left-side sidewall thickness (THKL₁) in the range of approximately 2 nm to approximately 4.5 nm (e.g., 3.37 nm), a right-side sidewall thickness (THKR₁) in the range of approximately 2 nm to approximately 4.5 nm (e.g., 2.79 nm), and a bottom silicide thickness (THKB₁) in the range of approximately 4 nm to approximately 6.5 nm (e.g., 4.53 nm).

The second silicide contact 404 has a workable depth (D₂) measured at a height from the top of a first nanosheet 406 to the bottom of the silicide contact in the range of approximately 14 nm to approximately 37 nm (e.g., 32.74 nm). The second silicide contact 404 has a height (H₂) in relation to STI below a bottom nanosheet 410 to the bottom of the second silicide contact 404 in the range of approximately 6 nm to approximately 28 nm (e.g., 11.5 nm). The second silicide contact 404 has a length (L₂) across the silicide contact measured at a height at a top of the first nanosheet 406 in the range of approximately 8 nm to approximately 16 nm (e.g., 13.64 nm). The second silicide contact 404 has a tangent angle of a bottom taper profile (θ₂) of the silicide contact in the range of approximately 95° to approximately 135° (e.g., 123°). The second silicide contact 404 has a left-side sidewall thickness (THKL₂) in the range of approximately 2 nm to approximately 4.5 nm (e.g., 2.9 nm), a right-side sidewall thickness (THKR₂) in the range of approximately 2 nm to approximately 4.5 nm (e.g., 3.14 nm), and a bottom silicide thickness (THKB₂) in the range of approximately 4 nm to approximately 6.5 nm (e.g., 4.64 nm).

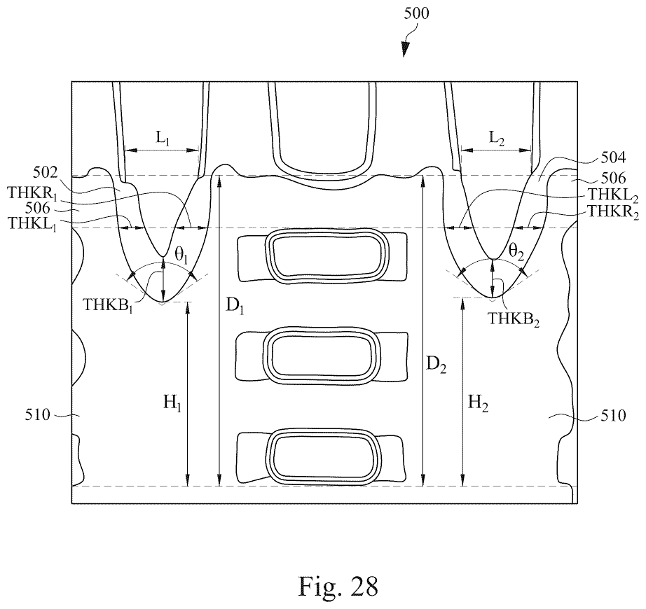

FIG. 28 depicts a cross-sectional view of an example semiconductor structure 500 with a first silicide contact 502 and a second silicide contact 504. Each of the first silicide contact 502 and the second silicide contact 504 has a tapered profile. Each of the first silicide contact 502 and the second silicide contact 504 extends below a first nanosheet 506.

The first silicide contact 502 has a workable depth (D₁) measured at a height from the top of the first nanosheet 506 to the bottom of the silicide contact in the range of approximately 14 nm to approximately 37 nm (e.g., 16.95 nm). The first silicide contact 502 has a height (H₁) in relation to STI below a bottom nanosheet 510 to the bottom of the first silicide contact 502 in the range of approximately 6 nm to approximately 28 nm (e.g., 25.13 nm). The first silicide contact 502 has a length (L₁) across the silicide contact measured at a height at a top of the first nanosheet 506 in the range of approximately 8 nm to approximately 16 nm (e.g., 10.12 nm). The first silicide contact 502 has a tangent angle of a bottom taper profile (θ₁) of the silicide contact in the range of approximately 95° to approximately 135° (e.g., 117.76°). The first silicide contact 502 has a left-side sidewall thickness (THKL₁) in the range of approximately 2 nm to approximately 4.5 nm (e.g., 3.9 nm), a right-side sidewall thickness (THKR₁) in the range of approximately 2 nm to approximately 4.5 nm (e.g., 3.07 nm), and a bottom silicide thickness (THKB₁) in the range of in the range of approximately 4 nm to approximately 6.5 nm (e.g., 5.61 nm).

The second silicide contact 504 has a workable depth (D₂) measured at a height from the top of the first nanosheet 506 to the bottom of the silicide contact in the range of approximately 14 nm to approximately 37 nm (e.g., 16.31 nm). The second silicide contact 504 has a height (H₂) in relation to STI below a bottom nanosheet 510 to the bottom of the second silicide contact 504 in the range of approximately 6 nm to approximately 28 nm (e.g., 25.83 nm). The second silicide contact 504 has a length (L₂) across the silicide contact measured at a height at a top of the first nanosheet 506 in the range of approximately 8 nm to approximately 16 nm (e.g., 9.6 nm). The second silicide contact 504 has a tangent angle of a bottom taper profile (θ₂) of the silicide contact in the range of approximately 95° to approximately 135° (e.g., 118.03°). The second silicide contact 504 has a left-side sidewall thickness (THKL₂) in the range of approximately 2 nm to approximately 4.5 nm (e.g., 3.52 nm), a right-side sidewall thickness (THKR₂) in the range of approximately 2 nm to approximately 4.5 nm (e.g., 3.22 nm), and a bottom silicide thickness (THKB₂) in the range of in the range of approximately 4 nm to approximately 6.5 nm (e.g., 4.35 nm).

In some aspects, the techniques described herein relate to a method, including: forming a dielectric liner in an opening above a source/drain (S/D) feature in a semiconductor structure; forming a recess in the S/D feature through the opening via plasma etching; removing a byproduct from forming the recess via a wet cleaning process; and forming a silicide contact that extends from a sidewall of the opening above the S/D feature to a bottom of the opening in the recess in the S/D feature.

In some aspects, the techniques described herein relate to a method, wherein the opening includes a tapered shape.

In some aspects, the techniques described herein relate to a method, wherein forming the recess includes forming the recess with the bottom of the opening in the recess extending below a first nanosheet.

In some aspects, the techniques described herein relate to a method, wherein forming the recess includes forming the recess with the bottom of the opening in the recess extending below a second nanosheet.

In some aspects, the techniques described herein relate to a method, wherein forming the dielectric liner includes forming the dielectric liner from silicon nitride (SiN).

In some aspects, the techniques described herein relate to a method, wherein the wet cleaning process includes a wet cleaning process using a fluorine derivative acid.

In some aspects, the techniques described herein relate to a method, wherein forming the silicide contact includes forming the silicide contact on the dielectric liner and the S/D feature in the recess.

In some aspects, the techniques described herein relate to a semiconductor device, including: a gate structure around a plurality of nanosheets; a source/drain (S/D) feature adjacent to the plurality of nanosheets; a dielectric liner above the S/D feature; a recess in the S/D feature that is below the S/D feature; and a silicide contact that extends from the dielectric liner above the S/D feature into the recess in S/D feature.

In some aspects, the techniques described herein relate to a semiconductor device, wherein a length across the silicide contact measured at a height at a top of a first nanosheet of the plurality of nanosheets is between about 8 nm to about 16 nm.

In some aspects, the techniques described herein relate to a semiconductor device, wherein the silicide contact includes a workable depth (D) measured at a height at a top of a first nanosheet of the plurality of nanosheets to a bottom of the silicide contact is between about 14 nm to about 37 nm.

In some aspects, the techniques described herein relate to a semiconductor device, wherein the silicide contact includes a height (H) in relation to STI below a bottom nanosheet of the plurality of nanosheets to a bottom of the silicide contact is between about 6 nm to about 28 nm.

In some aspects, the techniques described herein relate to a semiconductor device, wherein the silicide contact includes a length across the silicide contact measured at a height at a top of a first nanosheet of the plurality of nanosheets, a workable depth (D) measured at a height at a top of the first nanosheet of the plurality of nanosheets to a bottom of the recess, and the silicide contact includes an effective aspect ratio (D/L) that is between about 0.8 to about 4.

In some aspects, the techniques described herein relate to a semiconductor device, wherein the silicide contact includes a tangent angle of a bottom taper profile (θ) that is between about 95° to about 135°.

In some aspects, the techniques described herein relate to a semiconductor device, wherein the silicide contact includes a left-side sidewall thickness (THKL) and a right-side sidewall thickness (THKR) that are in a range of approximately 2 nm to approximately 4.5 nm, and a bottom Silicide thickness (THKB) in a range of approximately 4 nm to approximately 6.5 nm.

In some aspects, the techniques described herein relate to a method, including: forming a dielectric liner in an opening above a source/drain (S/D) feature in a semiconductor structure; dry etching a recess in the S/D feature through the opening; performing wet cleaning using a chemical with high wet etching selectivity of a dry etching byproduct in the recess to material of the S/D feature and material of the dielectric liner; and forming a silicide contact that extends from a sidewall of the opening above the S/D feature to a bottom of the opening in the recess in the S/D feature.

In some aspects, the techniques described herein relate to a method, wherein performing the wet cleaning includes performing the wet cleaning using a fluorine derivative acid at a concentration range from 200 ppm to 10 wt %.

In some aspects, the techniques described herein relate to a method, wherein the fluorine derivative acid includes one or more of HF, HBF₄, and NH₄BF₄.

In some aspects, the techniques described herein relate to a method, wherein dry etching the recess includes dry etching the recess using a gas mixture including one or more of CH₄, Ar, HBr, O₂, Cl₂, BCl₃, and N₂ gas.

In some aspects, the techniques described herein relate to a method, wherein forming the dielectric liner in the opening includes forming the dielectric liner using SiN.

In some aspects, the techniques described herein relate to a method, wherein forming the silicide contact includes forming the silicide contact using titanium silicide (TiSi), cobalt silicide (CoSi), nickel silicide (NiSi), or copper silicide (CuSi).

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A method, comprising:
forming a dielectric liner in an opening above a source/drain (S/D) feature in a semiconductor structure;
forming a recess in the S/D feature through the opening via plasma etching;
removing a byproduct from forming the recess via a wet cleaning process; and
forming a silicide contact that extends from a sidewall of the opening above the S/D feature to a bottom of the opening in the recess in the S/D feature.

2. The method of claim 1, wherein the opening comprises a tapered shape.

3. The method of claim 1, wherein forming the recess comprises forming the recess with the bottom of the opening in the recess extending below a first nanosheet.

4. The method of claim 1, wherein forming the recess comprises forming the recess with the bottom of the opening in the recess extending below a second nanosheet.

5. The method of claim 1, wherein forming the dielectric liner comprises forming the dielectric liner from silicon nitride (SiN).

6. The method of claim 1, wherein the wet cleaning process comprises a wet cleaning process using a fluorine derivative acid.

7. The method of claim 1, wherein forming the silicide contact comprises forming the silicide contact on the dielectric liner and the S/D feature in the recess.

8. A semiconductor device, comprising:
a gate structure around a plurality of nanosheets;
a source/drain (S/D) feature adjacent to the plurality of nanosheets;
a dielectric liner above the S/D feature;
a recess in the S/D feature that is below the S/D feature; and
a silicide contact that extends from the dielectric liner above the S/D feature into the recess in S/D feature.

9. The semiconductor device of claim 8, wherein a length across the silicide contact measured at a height at a top of a first nanosheet of the plurality of nanosheets is between about 8 nm to about 16 nm.

10. The semiconductor device of claim 8, wherein the silicide contact comprises a workable depth (D) measured at a height at a top of a first nanosheet of the plurality of nanosheets to a bottom of the silicide contact is between about 14 nm to about 37 nm.

11. The semiconductor device of claim 8, wherein the silicide contact comprises a height (H) in relation to STI below a bottom nanosheet of the plurality of nanosheets to a bottom of the silicide contact is between about 6 nm to about 28 nm.

12. The semiconductor device of claim 8, wherein the silicide contact comprises a length across the silicide contact measured at a height at a top of a first nanosheet of the plurality of nanosheets, a workable depth (D) measured at a height at a top of the first nanosheet of the plurality of nanosheets to a bottom of the recess, and the silicide contact comprises an effective aspect ratio (D/L) that is between about 0.8 to about 4.

13. The semiconductor device of claim 8, wherein the silicide contact comprises a tangent angle of a bottom taper profile (θ) that is between about 95° to about 135°.

14. The semiconductor device of claim 8, wherein the silicide contact comprises a left-side sidewall thickness (THKL) and a right-side sidewall thickness (THKR) that are in a range of approximately 2 nm to approximately 4.5 nm, and a bottom Silicide thickness (THKB) in a range of approximately 4 nm to approximately 6.5 nm.

15. A method, comprising:
forming a dielectric liner in an opening above a source/drain (S/D) feature in a semiconductor structure;
dry etching a recess in the S/D feature through the opening;
performing wet cleaning using a chemical with high wet etching selectivity of a dry etching byproduct in the recess to material of the S/D feature and material of the dielectric liner; and
forming a silicide contact that extends from a sidewall of the opening above the S/D feature to a bottom of the opening in the recess in the S/D feature.

16. The method of claim 15, wherein performing the wet cleaning comprises performing the wet cleaning using a fluorine derivative acid at a concentration range from 200 ppm to 10 wt %.

17. The method of claim 16, wherein the fluorine derivative acid comprises one or more of HF, HBF₄, and NH₄BF₄.

18. The method of claim 15, wherein dry etching the recess comprises dry etching the recess using a gas mixture comprising one or more of CH₄, Ar, HBr, O₂, Cl₂, BCl₃, and N₂ gas.

19. The method of claim 15, wherein forming the dielectric liner in the opening comprises forming the dielectric liner using SiN.

20. The method of claim 15, wherein forming the silicide contact comprises forming the silicide contact using titanium silicide (TiSi), cobalt silicide (CoSi), nickel silicide (NiSi), or copper silicide (CuSi).
